(19) United States
(12) Patent Application Publication
(10) Pub. No.: US 2018/0247834 A1
(43) Pub. Date: Aug. 30, 2018

(54) METHOD FOR MANUFACTURING SEMICONDUCTOR APPARATUS

(71) Applicant: SHIN-ETSU CHEMICAL CO., LTD., Tokyo (JP)

(72) Inventors: Koichi TSUDA, Sakai-shi (JP); Shuichi FUJII, Maebashi-shi (JP); Kazuaki SUMITA, Annaka-shi (JP); Akihiko OSAKI, Annaka-shi (JP); Toshio SHIOBARA, Annaka-shi (JP)

(73) Assignee: SHIN-ETSU CHEMICAL CO., LTD., Tokyo (JP)

(21) Appl. No.: 15/895,240

(22) Filed: Feb. 13, 2018

(30) Foreign Application Priority Data
Feb. 27, 2017 (JP) 2017-35505

(51) Int. Cl. H01L 21/56; H01L 21/48; H01L 23/29; H01L 23/31; H01L 23/498

(52) U.S. Cl. CPC H01L 21/561; H01L 21/563; H01L 21/4853; H01L 21/565; H01L 21/568; H01L 23/3128; H01L 23/3135; H01L 23/49816; H01L 23/295

(57) ABSTRACT

This is to provide a method for manufacturing a semiconductor apparatus which can shorten the manufacturing process of a semiconductor device, particularly a fan-out package without causing sealing defects such as voids or warpage, and can accomplish reduction in the manufacturing cost or improve in yield. There is provided a method for manufacturing a semiconductor apparatus which comprises preparing a semiconductor device-mounted substrate onto which a plurality of flip chip type semiconductor devices have been mounted onto a wiring layer formed on the substrate, collectively sealing a device-mounted surface of the semiconductor device-mounted substrate with a sealing material attached with a base material for sealing a semiconductor having a base material and a sealing resin layer containing an uncured or semi-cured thermosetting resin component formed on one surface of the base material, and removing the substrate from the collectively sealed semiconductor device-mounted substrate.

### FIELD OF THE INVENTION

The present invention relates to a method for manufacturing a semiconductor apparatus.

### DESCRIPTION OF THE RELATED ART

In recent years, miniaturization, thinning and high performance of electronic devices represented by mobile phones, smart phones and tablet terminals have been required, and semiconductor apparatus constituting the electronic devices have also been required to be miniaturized, thinned and high density packaging. As a semiconductor package manufacturing technology realizing such a requirement, a multichip module accommodating a plurality of semiconductor chips in one package and a wafer level package have been investigated and put to practical use. In recent years, a fan-out wafer level package technology attracts a great deal of attention. The fan-out wafer level package is a general term for packages that form a rewiring layer also outside the area of semiconductor devices by using the conventional wafer level rewiring technology. In a typical BGA (Ball Grid Array) type package as a type of semiconductor package, it was necessary to mount semiconductor devices on a package substrate and perform wire bonding, and in this fan-out wafer level package, a small package can be realized by replacing the package substrate, the wire wiring with thin film wiring bodies and bonding them to the semiconductor devices (see Patent Documents 1 to 4).

As a method for manufacturing such a fan-out wafer level package, there is a method called a chip-first method. In the chip-first method, employed is a method in which chips arranged at arbitrary intervals on a support substrate are firstly sealed with a resin, thereafter, the support substrate is removed to obtain a dummy wafer. A plurality of packages can be obtained by forming a rewiring layer onto the dummy wafer and then dividing the dummy wafer between the chips (see Patent Documents 5 and 6).

In addition, the fan-out wafer level package may be manufactured by a method called RDL (Redistribution Layer) first method. In the RDL first method, a rewiring layer is firstly formed onto a first support substrate, and a plurality of flip chip type semiconductor devices are mounted onto the rewiring layer. As an underfill material for sealing the space between the bumps of the flip chip, a precoat type underfill material and a capillary underfill material are used. After underfilling, a plurality of semiconductor devices are collectively sealed with a sealing resin. Thereafter, a second support substrate which is different from the first support substrate is bonded to the sealing resin side with a temporary fixing material. Then, the first support substrate is removed to expose the rewiring layer, and terminals for connection with the outside such as solder bumps are formed. A method of peeling off the second support substrate and dividing into individual pieces by dicing has been proposed. These manufacturing processes of the fan-out wafer level packages are extremely complicated and the number of processes is large, so that the manufacturing cost and lowering in yield are serious problems (see Patent Documents 7 to 9).

### PRIOR ART DOCUMENTS

### Patent Documents

Patent Document 1: Japanese Patent Laid-Open Publication No. Sho. 51-009587

Patent Document 2: Japanese Patent Laid-Open Publication No. Hei. 5-206368

Patent Document 3: Japanese Patent Laid-Open Publication No. Hei. 7-086502

Patent Document 4: Japanese Patent Laid-Open Publication No. 2004-056093

Patent Document 5: Japanese Patent Laid-Open Publication No. 2005-167191

Patent Document 6: U.S. Pat. No. 6,271,469

Patent Document 7: Japanese Patent Laid-Open Publication No. 2007-242888

Patent Document 8: Japanese Patent Laid-Open Publication No. 2013-042052

Patent Document 9: Japanese Patent Laid-Open Publication No. 2016-155735

### SUMMARY OF THE INVENTION

The present invention has been done to solve the above-mentioned problems, and an object thereof is to provide a method for manufacturing a semiconductor apparatus which can shorten the manufacturing process of a semiconductor device, particularly a fan-out package without causing sealing defects such as voids and warpage, and can accomplish reduction in the manufacturing cost and improvement in yield.

To accomplish the above-mentioned tasks, in the present invention, it is provided a method for manufacturing a semiconductor apparatus, which comprises preparing a semiconductor device-mounted substrate onto which a plurality of flip chip type semiconductor devices have been mounted onto a wiring layer formed on the substrate, collectively sealing a device-mounted surface of the semiconductor device-mounted substrate with a sealing material attached with a base material for sealing a semiconductor having a base material and a sealing resin layer containing an uncured or semi-cured thermosetting resin component formed on one surface of the base material, and removing the substrate from the collectively sealed semiconductor device-mounted substrate.

When such a method for manufacturing a semiconductor apparatus is employed, the manufacturing process of a semiconductor device, particularly a fan-out package can be shortened without causing sealing defects such as voids and warpage, and reduction in manufacturing cost and improvement in yield can be accomplished.

In addition, it is preferable that collective sealing with the sealing material attached with a base material for sealing a semiconductor is carried out at a molding temperature of 80° C. to 200° C., and a molding pressure of 0.2 to 30 MPa under reduced pressure of a vacuum pressure of 10,000 Pa or lower.

By carrying out the collective sealing under such conditions, the device-mounted surface of the semiconductor device-mounted substrate can be better and easily sealed.

In addition, after removing the substrate, it is preferable to form an electrode(s) on a surface exposed by removal of the substrate.

According to this procedure, a semiconductor apparatus in which an electrode(s) is/are formed on the wiring layer can be easily manufactured.

Also, after forming the electrode(s), it is preferable to divide into individual pieces by dicing.

According to this procedure, the semiconductor apparatus divided into individual pieces can be easily manufactured.

Further, as the base material, it is preferable to use a material which is a fiber-containing resin base material in which a thermosetting resin composition is impregnated into a fiber base material and cured, and has a linear expansion coefficient of 3 to 20 ppm/° C. in the range of 0° C. to 200° C.

By using such a base material, it is possible to suppress warpage in any process, such as after sealing the device-mounted surface with the sealing material attached with a base material for sealing a semiconductor, or after removal of the substrate.

As the sealing resin layer, it is preferable to use a material which contains an inorganic filler, an amount of the inorganic filler is 80 to 95% by mass based on the whole composition for forming the sealing resin layer, and a minimum melt viscosity is 0.1 to 300 Pa·s at 100° C. to 200° C. in the state before curing the sealing resin layer.

By using such a sealing resin layer, the device-mounted surface of the semiconductor device-mounted substrate can be better and easily sealed without causing voids and adhesion failure and warpage of the semiconductor apparatus to be manufactured can be further reduced.

In addition, it is preferable that underfill between the flip chip type semiconductor devices and the wiring layers is not carried out in advance, but carried out the underfill simultaneously with the collectively sealing a sealing material attached with a base material for sealing a semiconductor.

By doing so, it becomes not necessary to carry out the underfill separately, so that the manufacturing process can be further shortened.

Also, it is preferable to manufacture a fan-out wafer level package as the semiconductor apparatus.

Thus, the method for manufacturing a semiconductor apparatus of the present invention is particularly suitable for manufacturing a fan-out wafer level package.

According to the method for manufacturing a semiconductor apparatus of the present invention, by collectively sealing the device-mounted surface with the sealing material attached with a base material for sealing a semiconductor, a molded product having extremely high strength can be obtained due to reinforcing effect of the base material. Accordingly, removal of the substrate adhered to the wiring layer and formation of the terminal (electrode) on the wiring layer can be carried out without bonding the support substrate to the side of the sealing resin layer. That is, according to the present invention, bonding of the support substrate and removal of the support substrate that have been required to carry out separately in the conventional method can be omitted. Also, in the method for manufacturing a semiconductor apparatus of the present invention, warpage of the semiconductor apparatus can be suppressed by the base material of the sealing material attached with a base material for sealing a semiconductor, so that the degree of freedom of the physical properties of the sealing resin layer can be heightened. According to the procedure, it is possible to carry out mold underfill, which performs underfill and collective sealing of the device-mounted surface simultaneously. In other words, according to the present invention, it is possible to omit the underfill which needs to be separately carried out in the conventional method. Thus, according to the method for manufacturing a semiconductor apparatus of the present invention, some processes which had been necessary for the manufacture of the semiconductor apparatus, in particular, the fan-out wafer level package can be omitted (shortened) without causing sealing defects such as voids and warping, and can accomplish reduction in manufacturing cost or improvement in yield.

### BRIEF DESCRIPTION OF THE DRAWINGS

FIG. 1 is a schematic cross-sectional view showing one example of a flow in the case of manufacturing a fan-out wafer level package by the method for manufacturing a semiconductor apparatus of the present invention;

FIG. 2 is a schematic cross-sectional view showing one example of the sealing material attached with a base material for sealing a semiconductor to be used in the present invention;

FIG. 3 is a schematic cross-sectional view showing one example of the semiconductor apparatus manufactured by the method for manufacturing a semiconductor apparatus of the present invention; and

FIG. 4 is a schematic cross-sectional view showing one example of a flow in the case of manufacturing a fan-out wafer level package by the conventional method for manufacturing a semiconductor apparatus.

### DETAILED DESCRIPTION OF THE PREFERRED EMBODIMENTS

It has been desired to develop a method for manufacturing a semiconductor apparatus capable of shortening the manufacturing process of a semiconductor device, in particular, a fan-out package, without causing sealing defect such as voids, warpage, and capable of accomplishing reduction in manufacturing cost and improvement in yield.

The present inventors have intensively studied to solve the problems, and as a result, they have found that, in the RDL first method, the object can be accomplished by collectively sealing a device-mounted surface of a semiconductor device-mounted substrate by using a sealing material attached with a base material for sealing a semiconductor, and accomplished the present invention.

That is, the present invention relates to a method for manufacturing a semiconductor apparatus, which comprises preparing a semiconductor device-mounted substrate onto which a plurality of flip chip type semiconductor devices have been mounted onto a wiring layer formed on the substrate, collectively sealing a device-mounted surface of the semiconductor device-mounted substrate with a sealing material attached with a base material for sealing a semiconductor having a base material and a sealing resin layer containing an uncured or semi-cured thermosetting resin component formed on one surface of the base material, and removing the substrate from the collectively sealed semiconductor device-mounted substrate.

It is to be noted that the method for manufacturing a semiconductor apparatus of the present invention is preferably a method which comprises forming an electrode onto an exposed surface due to removal of the substrate after removing the substrate, and further dividing into pieces by dicing after forming the electrode.

In the following, the present invention will be described in detail with reference to the drawings, but the present invention is not limited thereto.

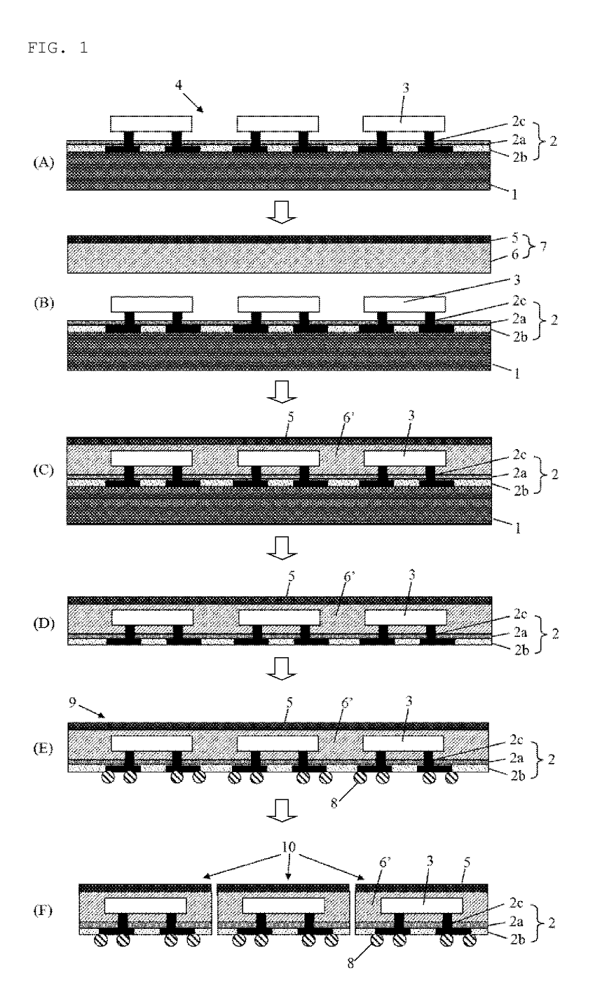

FIG. 1 is a schematic cross-sectional view showing one example of a flow in the case of manufacturing a fan-out wafer level package by the method for manufacturing a semiconductor apparatus of the present invention. In the method for manufacturing a semiconductor apparatus of FIG. 1, first, a semiconductor device-mounted substrate 4 in which a plurality of flip chip type semiconductor devices 3 are mounted onto wiring layers 2 (an insulating layer 2a, an insulating layer 2b, a plating pattern 2c) formed onto a substrate 1 is prepared (FIG. 1(A): preparation process). Next, a device-mounted surface of the semiconductor device-mounted substrate 4 is covered by a sealing resin layer 6 of the sealing material attached with a base material for sealing a semiconductor 7 having a base material 5 and the sealing resin layer 6 formed on one of the surfaces of the base material 5, and the sealing resin is allowed to enter into the space between the flip chip type semiconductor devices 3 and the wiring layers 2 and cured. According to this procedure, the sealing resin layer 6 becomes a sealing resin layer 6′ after curing (FIG. 1(B), (C): the sealing process). Next, the substrate 1 is removed by grinding or etching (FIG. 1(D): substrate removing process), and bumps 8 are formed onto the wiring layers 2 exposed by the removal of the substrate 1 (FIG. 1(E): bump forming process). Then, the thus obtained semiconductor apparatus assembly 9 is divided into pieces by dicing to manufacture the semiconductor apparatuses 10 (FIG. 1(F): dicing process).

In the following, the method for manufacturing a semiconductor apparatus of the present invention will be explained in more detail.

### <Preparation Process>

In the method for manufacturing a semiconductor apparatus of the present invention, first, a semiconductor device-mounted substrate onto which a plurality of flip chip type semiconductor devices have been mounted onto wiring layers formed on the substrate is prepared.

The substrate is not particularly limited and, for example, a glass substrate, a silicon wafer, a metal plate such as SUS (stainless steel), a plastic substrate such as polyamide and polyimide may be used.

The wiring layers are not particularly limited and, for example, wiring layers comprising an insulating layer and a plating pattern can be formed. The insulating layer is not particularly limited and, for example, an insulating layer containing a polyimide resin can be formed.

It is to be noted that, when the wiring layers are formed onto the substrate, a temporary adhesive layer may be formed between the substrate and the wiring layers. The temporary adhesive layer is not particularly limited and, for example, an UV-peelable adhesive such as an UV-curable adhesive, or a heat-peelable adhesive such as a heat-foamable adhesive may be used.

In addition, when the flip chip type semiconductor devices are mounted onto the wiring layers, underfilling between the semiconductor devices and the wiring layers may be carried out, or underfilling is not carried out at this stage and the space between the semiconductor devices and the wiring layers is kept to proceed the next process, and collective sealing of the device-mounted surface and underfilling may be carried out simultaneously in the sealing process which is the next process. It is preferable to carry out collective sealing of the device-mounted surface and underfilling simultaneously since the number of processes can be reduced.

When underfilling is carried out when the flip chip type semiconductor devices are mounted onto the wiring layers, underfilling may be carried out simultaneously with mounting of the semiconductor devices by using a film type or paste type and previously coating type underfill material, or underfilling may be carried out after mounting the semiconductor devices by capillary underfilling.

### <Sealing Process>

In the method for manufacturing a semiconductor apparatus of the present invention, the device-mounted surface of the semiconductor device-mounted substrate prepared in the preparation process is then collectively sealed by the sealing material attached with a base material for sealing a semiconductor having the base material and the sealing resin layer containing an uncured or semi-cured thermosetting resin component formed on one of the surfaces of the base material. More specifically, the device-mounted surface of the semiconductor device-mounted substrate is covered by the sealing resin layer of the sealing material attached with a base material for sealing a semiconductor, and the sealing resin layer is heated and cured to collectively sealing the device-mounted surface of the semiconductor device-mounted substrate.

It is to be noted that, in the case where the underfilling is carried out in the preparation process to seal the space between the semiconductor devices and the wiring layers, it is not necessary to allow the sealing resin to enter into the space between the semiconductor devices and the wiring layers in the sealing process. On the other hand, in the case of proceeding to the next process while keeping the space between the semiconductor devices and the wiring layers without carrying out the underfilling in the preparation process, collective sealing of the device-mounted surface and underfilling are preferably carried out simultaneously in the sealing process. Thus, in the present invention, collective sealing of the device-mounted surface and underfilling can be carried out simultaneously in the sealing process, so that it is not necessarily carried out the underfilling process separately, whereby the number of processes can be reduced.

The sealing process is preferably carried out at a molding temperature of 80° C. to 200° C., preferably 120° C. to 180° C., a molding pressure of 0.2 to 30 MPa, preferably 1 to 10 MPa, and a vacuum pressure of 10,000 Pa or lower, preferably under reduced pressure of 1 to 1,000 Pa.

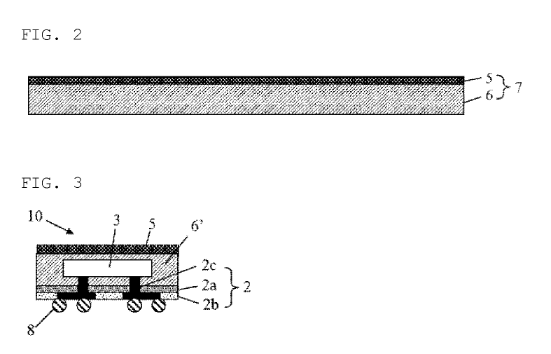

In the following, the sealing material attached with a base material for sealing a semiconductor used in the sealing process of the method for manufacturing a semiconductor apparatus of the present invention will be explained in more detail. FIG. 2 is a schematic cross-sectional view showing one example of the sealing material attached with a base material for sealing a semiconductor to be used in the present invention. The sealing material attached with a base material for sealing a semiconductor 7 shown in FIG. 2 has a base material 5 and a sealing resin layer 6 containing an uncured or semi-cured thermosetting resin component formed on one surface of the base material 5.

### [Base Material]

The base material constituting the sealing material attached with a base material for sealing a semiconductor is not particularly limited, and may be used an inorganic substrate, a metal substrate or an organic resin substrate depending on the linear expansion coefficient of the semiconductor device which becomes an object to be sealed. In particular, when an organic resin substrate is used, a fiber-containing organic resin substrate may be used.

A thickness of the base material is preferably 20 μm to 1 mm in either of the inorganic substrate, the metal substrate or the organic resin substrate, more preferably 30 μm to 500 μm. If it is 20 μm or more, it is preferable since it can suppress to be easily deformed due to being too thin, while if it is 1 mm or less, it is preferable since it can suppress the semiconductor apparatus itself becoming thick.

The linear expansion coefficient of the base material is preferably 3 to 20 ppm/° C. in the range of 0° C. to 200° C. in either of the inorganic substrate, the metal substrate or the organic resin substrate, more preferably 4 to 15 ppm/° C. If it is in this range, it is preferable since warpage can be suppressed in either of the processes after sealing the device-mounted surface of the sealing material attached with a base material for sealing a semiconductor or after removal of the substrate.

The inorganic substrate may be mentioned a ceramic substrate, a glass substrate and a silicon wafer, and the metal substrate may be mentioned copper and aluminum substrates whose surfaces are subjected to insulation treatment as representative examples. The organic resin substrate may be mentioned a resin-impregnated fiber base material in which a thermosetting resin and a filler are impregnated into a fiber base material, and further, a fiber-containing resin base material in which a thermosetting resin is semi-cured or cured, and a resin substrate in which a thermosetting resin is molded to a substrate shape. Representative examples may include a BT (bismaleimide triazine) resin substrate, a glass epoxy substrate and an FRP (fiber reinforced plastic) substrate.

The thermosetting resin to be used for the organic resin substrate is not particularly limited, and may be mentioned a BT resin, an epoxy resin or the like, and an epoxy resin, a silicone resin, a hybrid resin comprising an epoxy resin and a silicone resin, and further a cyanate ester resin, or the like, which are generally used for sealing the semiconductor devices and exemplified by the following.

It is to be noted that, as the thermosetting resin to be impregnated into the fiber base material, for example, when a sealing material attached with a base material for sealing a semiconductor of the present invention is to be manufactured by using a resin-impregnated fiber base material which uses a thermosetting epoxy resin or a fiber-containing resin base material which is semi-cured after impregnating the epoxy resin as a base material, the thermosetting resin to be used for the sealing resin layer formed onto one of the surfaces of the base material is preferably also the epoxy resin. Thus, when the thermosetting resin impregnated into the substrate and the thermosetting resin to be used for the sealing resin layer formed onto one of the surfaces of the base material are the same kinds, it is preferable since the resins can be simultaneously cured when the device-mounted surface of the semiconductor device-mounted substrate is collectively sealed, whereby more firm sealing function can be accomplished.

The base material is particularly preferably a fiber-containing resin base material in which a thermosetting resin composition is impregnated into a fiber base material and cured. In the following, the fiber-containing resin base material in which a thermosetting resin composition is impregnated into a fiber base material and cured is explained in more detail.

### [Fiber Base Material]

As a fiber base material which can be used as an organic resin substrate, there may be exemplified by, for example, inorganic fiber such as carbon fiber, glass fiber, quartz glass fiber and metal fiber, and organic fiber such as aromatic polyamide fiber, polyimide fiber and polyamideimide fiber, and further, silicon carbide fiber, titanium carbide fiber, boron fiber and alumina fiber, and any material may be used depending on the characteristics of the product. The most preferable fiber base material may be exemplified by glass fiber, quartz glass fiber or carbon fiber. Among these, glass fiber or quartz glass fiber having high insulating properties is particularly preferable.

### [Thermosetting Resin Composition]

The thermosetting resin composition to be impregnated into the fiber base material is a material containing a thermosetting resin.

### (Thermosetting Resin)

The thermosetting resin to be used in the thermosetting resin composition is not particularly limited, and may be mentioned a resin which is generally used for sealing the semiconductor device such as an epoxy resin, a silicone resin, a hybrid resin comprising an epoxy resin and a silicone resin, and a cyanate ester resin. In addition, a thermosetting resin such as a BT resin may be also used.

### <<Epoxy Resin>>

In the sealing material attached with a base material for sealing a semiconductor to be used in the present invention, the epoxy resin which can be used in the thermosetting resin composition is not particularly limited, and may be mentioned, for example, a conventionally known epoxy resin which is a liquid state or a solid at the room temperature including a biphenol type epoxy resin such as a bisphenol A type epoxy resin, a bisphenol F type epoxy resin, a 3,3′,5,5′-tetramethyl-4,4′-biphenol type epoxy resin and a 4,4′-biphenol type epoxy resin; a phenol-novolac type epoxy resin, a cresol novolac type epoxy resin, a bisphenol A novolac type epoxy resin, a naphthalene diol type epoxy resin, a trisphenylol methane type epoxy resin, a tetrakisphenylol ethane type epoxy resin and an epoxy resin in which an aromatic ring of a phenol dicyclopentadiene novolac type epoxy resin is hydrogenated, an alicyclic epoxy resin, or the like. In addition, an epoxy resin other than the above may be used in combination, if necessary, depending on the purposes with a certain amount.

In the thermosetting resin composition containing the epoxy resin, a curing agent of the epoxy resin may be blended. Such a curing agent which can be used may be mentioned a phenol-novolac resin, various kinds of amine derivatives, an acid anhydride or a material in which an acid anhydride group is partially ring-opened to form a carboxylic acid. Among these, a phenol-novolac resin is preferably used to secure reliability of the semiconductor apparatus manufactured by using the sealing material attached with a base material for sealing a semiconductor. In particular, a mixing ratio of the epoxy resin and the phenol-novolac resin is preferably made that a ratio of an epoxy group and a phenolic hydroxyl group to be 1:0.8 to 1.3.

Further, an imidazole derivative, a phosphine derivative, an amine derivative or a metal compound such as an organic aluminum compound may be used as a reaction promoter (a catalyst) to promote the reaction of the epoxy resin and the curing agent.

Various additives may be further blended in the thermosetting resin composition containing the epoxy resin, if necessary. For example, for the purpose of improving the properties of the resin, additives such as various thermoplastic resins, thermoplastic elastomers, organic synthetic rubbers, low stress agents such as silicone-based materials, waxes and halogen trapping agents may be appropriately added and blended, depending on the purposes.

### <<Silicone Resin>>

In the sealing material attached with a base material for sealing a semiconductor used in the present invention, the silicone resin which can be used in the thermosetting resin composition is not particularly limited and may be mentioned, for example, a thermosetting or UV curable silicone resin. In particular, the thermosetting resin composition containing the silicone resin preferably contains an addition curable silicone resin composition. The addition curable silicone resin composition may be particularly preferably a composition comprising (A) an organic silicon compound having nonconjugated double bonds (for example, an alkenyl group-containing diorganopolysiloxane), (B) an organohydrogen polysiloxane, and (C) a platinum-based catalyst as essential components. In the following, these Components (A) to (C) are explained.

### Component (A): Organic Silicon Compound Having Nonconjugated Double Bonds

The organic silicon compound having nonconjugated double bonds of Component (A) may be exemplified by an organopolysiloxane such as a linear diorganopolysiloxane in which both-terminals of the molecular chain are sealed by aliphatic unsaturated group-containing triorganosiloxy groups represented by the following general formula (a),

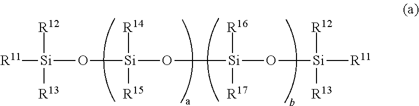

wherein, R¹¹ represents a monovalent hydrocarbon group containing nonconjugated double bonds, each of R¹² to R¹⁷ independently represents the same or different monovalent hydrocarbon groups, and repeating units “a” and “b” are integers satisfying 0≤a≤500, 0≤b≤250, and 0≤a+b≤500.

In the general formula (a), R¹¹ is a monovalent hydrocarbon group containing nonconjugated double bonds, preferably a monovalent hydrocarbon group containing nonconjugated double bonds having an aliphatic unsaturated bond represented by an alkenyl group having 2 to 8 carbon atoms, particularly preferably having 2 to 6 carbon atoms.

In the general formula (a), each of R¹² to R¹⁷ independently represents the same or different monovalent hydrocarbon group, and may be mentioned an alkyl group, an alkenyl group, an aryl group, and an aralkyl group each preferably having 1 to 20 carbon atoms, particularly preferably 1 to 10 carbon atoms. Among these, each of R¹⁴ to R¹⁷ is more preferably a monovalent hydrocarbon group excluding an aliphatic unsaturated bond, particularly preferably an alkyl group, an aryl group, an aralkyl group each having no aliphatic unsaturated bond such as an alkenyl group. Further, among these, each of R¹⁶ and R¹⁷ is preferably an aromatic monovalent hydrocarbon group, particularly preferably an aryl group having 6 to 12 carbon atoms such as a phenyl group and a tolyl group.

In the general formula (a), “a” and “b” are integers satisfying 0≤a≤500, 0b250, and 0≤a+b≤500, “a” is preferably 10≤a≤500, “b” is preferably 0≤b≤150, and “a”+“b” preferably satisfy 10≤a+b≤500.

The organopolysiloxane represented by the general formula (a) can be obtained, for example, by an alkali equilibration reaction of a cyclic diorganopolysiloxane such as cyclic diphenylpolysiloxane and cyclic methyl-phenylpolysiloxane, and a disiloxane constituting a terminal group such as diphenyltetravinyldisiloxane and divinyltetraphenyldisiloxane, and in this case, in the equilibration reaction by an alkali catalyst (particularly a strong alkali such as KOH), even in a small amount of catalyst, polymerization proceeds in an irreversible reaction, so that only ring-opening polymerization proceeds quantitatively and the terminal blocking rate is high, so a silanol group and a chlorine component are generally not contained.

The organopolysiloxane represented by the general formula (a) may be specifically exemplified by the following materials,

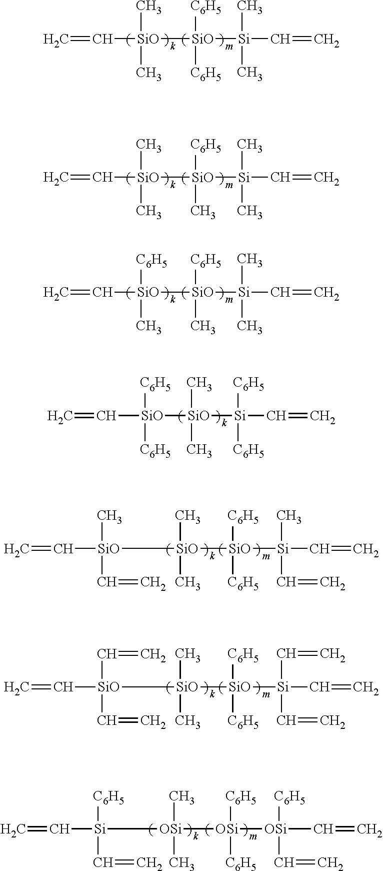

In the formulae, recurring units “k” and “m” are integers satisfying 0≤k≤500, 0≤m≤250, and 0≤k+m≤500, and preferably integers satisfying 5≤k+m≤250, and 0≤m/(k+m)≤0.5.

As Component (A), in addition to the organopolysiloxane having a linear structure represented by the general formula (a), an organopolysiloxane having a three-dimensional network structure including a tri-functional siloxane unit and a tetra-functional siloxane unit may also be used in combination, if necessary. Such an organic silicon compound having nonconjugated double bonds may be used a single kind alone or two or more kinds in admixture.

The amount of the group having nonconjugated double bonds in the organic silicon compound having nonconjugated double bonds (for example, a monovalent hydrocarbon group having a double bond such as an alkenyl group bonded to an Si atom) of Component (A) is preferably 0.1 to 20 mol % based on the entire monovalent hydrocarbon groups (all the monovalent hydrocarbon groups bonded to the Si atom), more preferably 0.2 to 10 mol %, and particularly preferably 0.2 to 5 mol %. If the amount of the group having the nonconjugated double bonds is 0.1 mol % or more, when the composition is cured, good cured product can be obtained, while if it is 20 mol % or less, it is preferable since the mechanical characteristics when it is cured are good.

In addition, the organic silicon compound having nonconjugated double bonds of Component (A) preferably has an aromatic monovalent hydrocarbon group (the aromatic monovalent hydrocarbon group bonded to the Si atom), and the content of the aromatic monovalent hydrocarbon group is preferably 0 to 95 mol % based on the whole monovalent hydrocarbon group (all the monovalent hydrocarbon group bonded to the Si atom), more preferably 10 to 90 mol %, and particularly preferably 20 to 80 mol %. If the aromatic monovalent hydrocarbon group is contained in the resin with a suitable amount, there are merits that mechanical characteristics when it is cured are good and it can be easily produced.

### Component (B): Organohydrogen Polysiloxane

As Component (B), an organohydrogen polysiloxane having two or more hydrogen atoms bonded to the silicon atom (hereinafter referred to as an “SiH group”) in one molecule is preferable. If the organohydrogen polysiloxane having two or more SiH groups in one molecule is employed, it acts as a crosslinking agent, and a cured product can be formed by subjecting to addition reaction of the SiH group in Component (B) and the nonconjugated double bond-containing group such as a vinyl group of Component (A) and other alkenyl groups.

The organohydrogen polysiloxane of Component (B) preferably has an aromatic monovalent hydrocarbon group. Thus, if it is an organohydrogen polysiloxane having an aromatic monovalent hydrocarbon group, compatibility with Component (A) can be heightened. Such an organohydrogen polysiloxane may be used a single kind alone or two or more kinds in admixture, and, for example, an organohydrogen polysiloxane having an aromatic hydrocarbon group can be contained as a part or whole of Component (B).

The organohydrogen polysiloxane of Component (B) is not particularly limited and may be mentioned, for example, 1,1,3,3-tetramethyldisiloxane, 1,3,5,7-tetramethylcyclotetrasiloxane, tris(dimethylhydrogensiloxy)methylsilane, tris(dimethylhydrogensiloxy)phenylsilane, 1-glycidoxypropyl-1,3,5,7-tetramethylcyclotetrasiloxane, 1,5-glycidoxypropyl-1,3,5,7-tetramethylcyclotetrasiloxane, 1-glycidoxypropyl-5-trimethoxysilylethyl-1,3,5,7-tetramethylcyclotetrasiloxane, a both-terminals trimethylsiloxy group-blocked methylhydrogenpolysiloxane, a both-terminals trimethylsiloxy group-blocked dimethylsiloxane-methylhydrogensiloxane copolymer, a both-terminals dimethylhydrogensiloxy group-blocked dimethylpolysiloxane, a both-terminals dimethylhydrogensiloxy group-blocked dimethyl-siloxane-methylhydrogensiloxane copolymer, a both-terminals trimethylsiloxy group-blocked methylhydrogensiloxane-diphenylsiloxane copolymer, a both-terminals trimethylsiloxy group-blocked methylhydrogensiloxane-diphenylsiloxane-dimethylsiloxane copolymer, trimethoxysilane polymer, a copolymer comprising a (CH₃)₂HSiO_{1/2} unit and an SiO_{4/2} unit, a copolymer comprising a (CH₃)₂HSiO_{1/2} unit, an SiO_{4/2} unit and a (C₆H₅) SiO_{3/2} unit.

In addition, a compound shown by the following structure, or an organohydrogen polysiloxane obtained by using these compounds as a material may be also used.

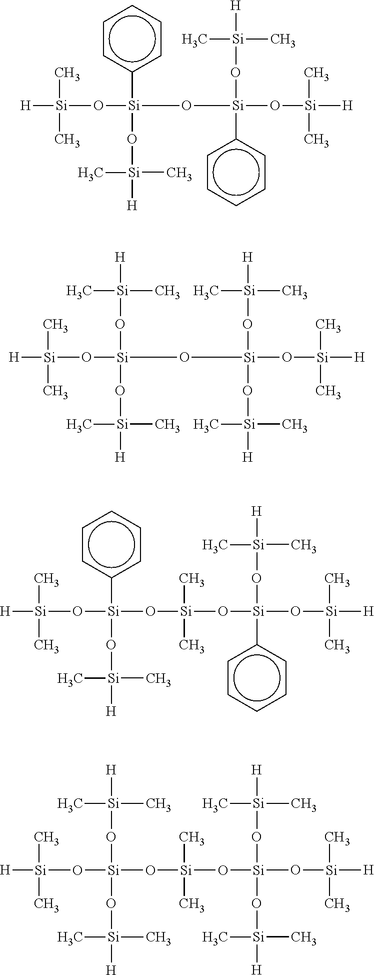

The molecular structure of the organohydrogen polysiloxane of Component (B) may be any of a linear, a cyclic, a branched, or a three-dimensional network structure, and a number of the silicon atoms in one molecule (or a polymerization degree in the case of a polymer) is preferably 2 or more, more preferably 3 to 500, and particularly preferably 4 to 300 or so.

The blending amount of the organohydrogen polysiloxane of Component (B) is preferably such an amount that a number of the SiH group in Component (B) becomes 0.7 to 3.0 based on one group having nonconjugated double bonds such as an alkenyl group of Component (A), particularly preferably 1.0 to 2.0.

### Component (C): Platinum-Based Catalyst

The platinum-based catalyst of Component (C) may be mentioned, for example, chloroplatinic acid, an alcohol-modified chloroplatinic acid and a platinum complex having a chelate structure. These may be used a single kind alone or two or more kinds in combination.

The blending amount of the platinum-based catalyst of Component (C) may be an effective amount for curing (the so-called catalytic amount), and in general, it is preferably 0.1 to 500 ppm in terms of a mass of the platinum group metal based on the total mass of Component (A) and Component (B) as 100 parts by mass, particularly preferably in the range of 0.5 to 100 ppm.

### <<Hybrid Resin Comprising Epoxy Resin and Silicone Resin>>

In the sealing material attached with a base material for sealing a semiconductor used in the present invention, the hybrid resin comprising an epoxy resin and a silicone resin which can be used in the thermosetting resin composition is not particularly limited, and may be mentioned, for example, those used in the epoxy resin and the silicone resin mentioned above. The hybrid resin herein mentioned means a material which forms a co-crosslinking structure by reacting with each other at the time of curing.

### <<Cyanate Ester Resin>>

In the sealing material attached with a base material for sealing a semiconductor used in the present invention, the cyanate ester resin which can be used as the thermosetting resin composition is not particularly limited, and may be mentioned, for example, a resin composition in which a cyanate ester compound or an oligomer thereof, and either one of or both of a phenol compound and dihydroxynaphthalene is/are blended as a curing agent(s).

### Cyanate Ester Compound or Oligomer Thereof

The component to be used as the cyanate ester compound or an oligomer thereof is a material represented by the following general formula (b),

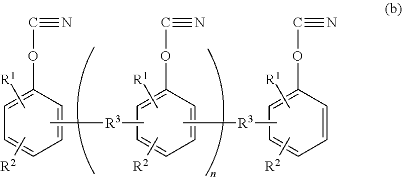

wherein, R¹ and R² each represent a hydrogen atom or an alkyl group having 1 to 4 carbon atoms, R³ represents any of

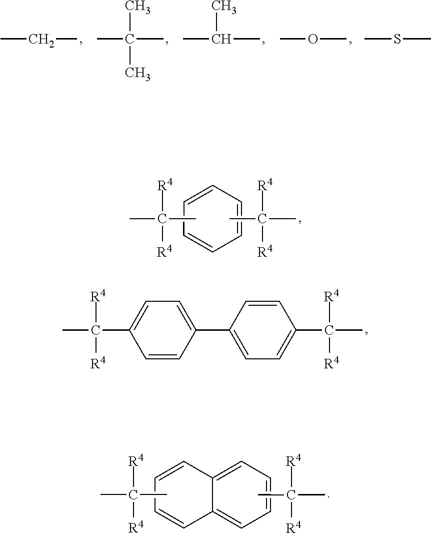

R⁴ represents a hydrogen atom or a methyl group and the recurring unit “n” is an integer of 0 to 30.

Here, the cyanate ester compound is a material having two or more cyanate groups in one molecule, and more specifically, a cyanate ester of a polyaromatic ring divalent phenol, for example, there may be mentioned bis(3,5-dimethyl-4-cyanatephenyl)methane, bis(4-cyanate-phenyl)methane, bis(3-methyl-4-cyanatephenyl)methane, bis(3-ethyl-4-cyanatephenyl)methane, bis(4-cyanatephenyl)-1,1-ethane, bis(4-cyanatephenyl)-2,2-propane, di(4-cyanatephenyl) ether, di(4-cyanatephenyl) thioether, a polycyanate ester of a polyvalent phenol, for example, a phenol novolac type cyanate ester, a cresol-novolac type cyanate ester, a phenylaralkyl type cyanate ester, a biphenylaralkyl type cyanate ester and a naphthalenearalkyl type cyanate ester.

The cyanate ester compound can be obtained by reacting a phenol and cyanogen chloride under a basic condition. The cyanate ester compound may be appropriately selected, from its structure, among those having a wide range of characteristics from a solid state material having a softening point of 106° C. to a liquid state material at a normal temperature depending on the uses.

Among these, those having a small equivalent of cyanate groups, i.e., those having a small molecular weight between the functional groups can give a cured product having low curing shrinkage, low thermal expansion and high Tg (glass transition temperature). Those having a large cyanate group equivalent are slightly lowered in Tg, but the triazine crosslinking interval becomes flexible, and low elasticity, high toughness and low water absorption can be expected.

It is to be noted that the chlorine bonded to or remaining in the cyanate ester compound is preferably 50 ppm or less, more preferably 20 ppm or less. If it is 50 ppm or less, during long-term high temperature storage, there is less possibility of causing corrosion of an oxidized Cu frame, Cu wire or Ag plating by liberated chlorine or a chlorine ion by thermal decomposition, and causing peeling or electric failure. In addition, insulating properties of the resin become good.

### Curing Agent

In general, as a curing agent or a curing catalyst of the cyanate ester resin, a metal salt, a metal complex, a phenolic hydroxyl group having an active hydrogen or a primary amine is used, and in the sealing material attached with a base material for sealing a semiconductor used in the present invention, a phenol compound or dihydroxynaphthalene is particularly suitably used.

The phenol compound which can be suitably used as the curing agent of the cyanate ester resin is not particularly limited, and there may be exemplified by a material represented by the following general formula (c),

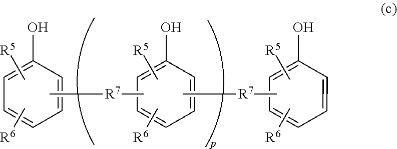

wherein, R⁵ and R⁶ each represent a hydrogen atom or an alkyl group having 1 to 4 carbon atoms, R⁷ represents any of

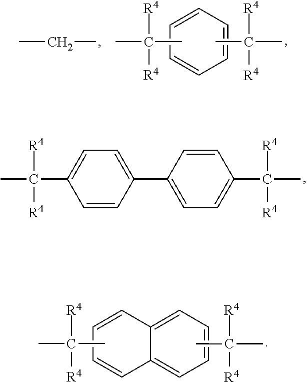

R⁴ represents a hydrogen atom or a methyl group and the recurring unit “p” is an integer of 0 to 30.

Here, the phenol compound may be mentioned a phenol resin having two or more phenolic hydroxyl groups in one molecule, a bisphenol F type resin, a bisphenol A type resin, a phenol-novolac resin, a phenolaralkyl type resin, a biphenylaralkyl type resin and a naphthalenearalkyl type resin, and among these, one kind may be used singly or two or more kinds may be used in combination.

The phenol compound having a small phenolic hydroxyl equivalent, for example, those having a hydroxyl equivalent of 120 or less have high reactivity with the cyanate group and the curing reaction proceeds even at a low temperature of 120° C. or lower. In this case, the molar ratio of the hydroxyl group to the cyanate group should be made small. A preferable range is 0.05 to 0.11 mol based on 1 mol of the cyanate group. In this case, a cured product with little curing shrinkage, low thermal expansion and high Tg can be obtained.

On the other hand, a material having a large phenolic hydroxyl equivalent, for example, a material having a hydroxyl equivalent of 175 or more can give a composition reactivity with the cyanate group of which is suppressed, and having good preservability and good fluidity. A preferable range is 0.1 to 0.4 mol based on 1 mol of the cyanate group. In this case, while Tg is slightly lowered, a cured product with low water absorption can be obtained. These phenol resins may also be used in combination of two or more kinds to obtain desired characteristics of the cured product and curability.

The dihydroxynaphthalene which can be suitably used as a curing agent of the cyanate ester resin is represented by the following general formula (d).

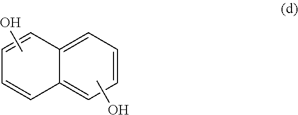

Here, the dihydroxynaphthalene may be mentioned 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 2,6-dihydroxynaphthalene and 2,7-dihydroxynaphthalene. Among these, 1,2-dihydroxynaphthalene, 1,3-dihydroxynaphthalene and 1,6-dihydroxynaphthalene each having the melting point of 130° C. have extremely high reactivity, so that these promote a cyclization reaction of the cyanate group with a small amount. In the case of 1,5-dihydroxynaphthalene and 2,6-dihydroxynaphthalene having the melting point of 200° C. or higher, the reaction is relatively suppressed.

In the case where these dihydroxynaphthalenes are used alone, it has a small molecular weight between the functional groups and a rigid structure so that a cured product with little curing shrinkage and high Tg can be obtained. In addition, if the compound is used in combination with a phenol compound having a large hydroxyl equivalent which has two or more hydroxyl groups in one molecule, curability can be adjusted.

The halogen element and the alkali metal in the phenol compound and dihydroxynaphthalene are preferably 10 ppm or less by the extraction at 120° C. under 2 atm, particularly preferably 5 ppm or less.

### (Colorant)

In the sealing material attached with a base material for sealing a semiconductor used in the present invention, the thermosetting resin composition preferably contains a colorant in addition to the thermosetting resin. When the thermosetting resin composition contains the colorant, appearance failure can be suppressed and laser marking property can be improved.

The colorant to be used is not particularly limited, and conventionally known pigments or dyes may be used alone or in combination of two or more kinds. In particular, from the viewpoints of improving appearance and laser marking property, a black color type colorant is preferably used.

The black color type colorant may be mentioned, for example, carbon black (furnace black, channel black, acetylene black, thermal black and lamp black), graphite, copper oxide, manganese dioxide, an azo-based pigment (azomethine black), aniline black, perylene black, titanium black, cyanine black, activated charcoal, ferrite (nonmagnetic ferrite and magnetic ferrite), magnetite, chromium oxide, iron oxide, molybdenum disulfide, a chromium complex, a composite oxide-based black pigment, an anthraquinone-based organic black pigment, or the like, and among these, carbon black is preferably used.

The colorant is preferably contained in the amount of 0.1 to 30 parts by mass based on 100 parts by mass of the thermosetting resin composition, particularly preferably 1 to 15 parts by mass.

If the blending amount of the colorant is 0.1 part by mass or more, coloring of the base material becomes good, appearance failure can be suppressed and laser marking property becomes good. Also, if the blending amount of the colorant is 30 parts by mass or less, it is possible to prevent the workability from being significantly lowered due to increase in the viscosity of the thermosetting resin composition to be impregnated into the fiber base material when the base material is produced.

### (Inorganic Filler)

In the sealing material attached with a base material for sealing a semiconductor used in the present invention, an inorganic filler may be blended in the thermosetting resin composition. The inorganic filler to be blended may be mentioned, for example, silica such as fused silica and crystalline silica, alumina, silicon nitride, aluminum nitride, aluminosilicate, boron nitride, glass fiber and antimony trioxide.

In particular, when the thermosetting resin composition contains an epoxy resin, those previously surface treated by a coupling agent such as a silane coupling agent and a titanate coupling agent may be blended as the inorganic filler to be added, to strengthen the bonding strength of the epoxy resin and the inorganic filler.

Such a coupling agent preferably used may be mentioned, for example, an epoxy-functional alkoxysilane such as γ-glycidoxypropyltrimethoxysilane, γ-glycidoxypropylmethyldiethoxysilane and β-(3,4-epoxycyclohexyl)-ethyltrimethoxysilane; an amino-functional alkoxysilane such as N-β-(aminoethyl)-γ-aminopropyltrimethoxysilane, γ-aminopropyltriethoxysilane and N-phenyl-γ-aminopropyltrimethoxysilane; and a mercapto-functional alkoxysilane such as γ-mercaptopropyltrimethoxysilane. It is to be noted that the blending amount and a surface treatment method of the coupling agent to be used for the surface treatment is not particularly limited.

The blending amount of the inorganic filler is preferably 100 to 1,300 parts by mass based on the total mass of the resin components such as the epoxy resin and the silicone resin as 100 parts by mass in the thermosetting resin composition, particularly preferably 200 to 1,000 parts by mass. If it is 100 parts by mass or more, sufficient strength can be obtained, while if it is 1,300 parts by mass or less, failure in filling property due to lowering in fluidity can be suppressed, and as a result, the semiconductor devices mounted onto the substrate or the semiconductor devices formed onto the wafer can be sealed well. It is to be noted that the inorganic filler is preferably contained in the range of 50 to 95% by mass based on the whole thermosetting resin composition, particularly preferably 60 to 90% by mass.

In the case where the base material is made, for example, a fiber-containing resin base material in which a thermosetting resin composition is impregnated into a fiber base material and cured, the linear expansion coefficient of the base material can be adjusted by the kind of the resin to be used in the thermosetting resin composition to be impregnated into the fiber base material or the blending amount of the additive(s) such as an inorganic filler. In addition, the thermosetting resin composition is impregnated into the fiber base material and semi-cured, and then, a plural sheets of the fiber base materials are laminated and pressed to make a multi-layered structure, which can be then used.

### [Sealing Resin Layer]

As shown in FIG. 2, the sealing material attached with a base material for sealing a semiconductor 7 to be used in the method for manufacturing a semiconductor apparatus of the present invention has a sealing resin layer 6 on one of the surfaces of the base material 5. The sealing resin layer 6 contains an uncured or semi-cured thermosetting resin component. The sealing resin layer 6 has a role of collectively sealing a device-mounted surface of the semiconductor device-mounted substrate onto which the semiconductor devices have been mounted.

The thickness of the sealing resin layer is not particularly limited, and preferably 20 μm or more and 2,000 μm or less. If it is 20 μm or more, it is preferable since it is sufficient to seal the semiconductor device-mounted surface of various substrates on which the semiconductor devices are mounted, and occurrence of failure in filling property due to being too thin can be suppressed, while if it is 2,000 μm or less, it is preferable since it is possible to prevent the sealed semiconductor apparatus from becoming too thick.

The viscosity of the sealing resin layer is preferably from 0.1 to 300 Pa·s as the minimum melt viscosity from 100° C. to 200° C., and more preferably 1 to 200 Pa·s. It is to be noted that, in the present specification, when the viscosity is measured continuously from 100° C. to 200° C. with a temperature raising rate of 5° C./min by using a parallel plate type viscoelasticity measuring device (device name: MR-300, manufactured by Rheology Corporation), and the lowest value is made a measured value of the minimum melt viscosity. If the minimum melt viscosity is 200 Pa·s or lower, the filling property at the time of molding is not excessively lowered, so that there is no fear of causing voids and adhesion failure. In addition, if the minimum melt viscosity is 1 Pa·s or more, the fluidity never becomes too high, so that there is no fear of the resin flows out of the mold and the thickness of the molded article becomes thinner than the set thickness, or causing occurrence of voids.

### [Thermosetting Resin Component]

The composition for forming the sealing resin layer contains a thermosetting resin component. The thermosetting resin is not particularly limited, and in general, it is preferably a thermosetting resin such as a liquid epoxy resin or a solid epoxy resin, a silicone resin, a hybrid resin comprising an epoxy resin and a silicone resin, or a cyanate ester resin, to be used for sealing the semiconductor device. In particular, the thermosetting resin is preferably a material containing any of an epoxy resin, a silicone resin, a hybrid resin comprising an epoxy resin and a silicone resin, or a cyanate ester resin, each of which solidifies at lower than 50° C. and melts at 50° C. or higher and 150° C. or lower.

Such an epoxy resin, a silicone resin, a hybrid resin comprising an epoxy resin and a silicone resin, and a cyanate ester resin may be exemplified by the same materials as exemplified by the thermosetting resin contained in the thermosetting resin composition to be impregnated into the fiber base material as mentioned above.

### [Thermoplastic Resin Component]

In the sealing material attached with a base material for sealing a semiconductor used in the present invention, the sealing resin layer may contain or may not contain the thermoplastic resin component, and when the thermoplastic resin component is contained, the blending amount of the thermoplastic resin component is preferably 2% by mass or less based on the whole composition for forming the sealing resin layer.

In general, the thermoplastic resin component is used as a component to provide flexibility to the sealing resin layer, and in the conventional resin sheet, it has been added to improve handling property and to retain the sheet shape. In the sealing material attached with a base material for sealing a semiconductor to be used in the present invention, since the structure is such that the sealing resin layer is supported by the substrate, even if the sealing resin layer does not contain the thermoplastic resin component, it becomes the material that the handling property is good and the sheet shape is retained.

The thermoplastic resin may be mentioned, for example, various kinds of acrylic copolymer such as a polyacrylic acid ester; a styrene-acrylate-based copolymer; a rubbery polymer such as butadiene rubber, styrene-butadiene rubber (SBR), an ethylene-vinyl acetate copolymer (EVA), isoprene rubber and acrylonitrile rubber; an urethane-based elastomer; a silicone-based elastomer; and a polyester-based elastomer.

### [Inorganic Filler]

In addition, in the composition for forming the sealing resin layer, an inorganic filler may be blended as in the thermosetting resin composition to be impregnated into the fiber base material. The inorganic filler may be exemplified by the same materials as those to be blended in the thermosetting resin composition to be impregnated into the fiber base material as mentioned above.

The blending amount of the inorganic filler is preferably 500 to 1,800 parts by mass based on the total mass of the resin components such as the epoxy resin and the silicone resin in the thermosetting resin composition as 100 parts by mass, particularly preferably 600 to 1,300 parts by mass, and further preferably 700 to 1,000 parts by mass. If it is 500 parts by mass or more, it is possible to suppress the difference in the linear expansion coefficient from the substrate from becoming large, which is suitable for suppressing warpage of the semiconductor apparatus, while if it is 1,800 parts by mass or less, failure in filling property due to lowering in fluidity is suppressed, and as a result, the semiconductor devices mounted onto the substrate can be well sealed. It is to be noted that the inorganic filler is preferably contained in the range of 80 to 95% by mass based on the whole thermosetting resin composition, particularly preferably 85 to 93% by mass.

The particle size of the inorganic filler is not particularly limited, and the average particle diameter is preferably from 0.1 μm to 40 μm, particularly preferably from 2 μm to 35 μm in view of moldability and fluidity. In the case where underfilling is also carried out in the sealing process, a flip chip type semiconductor device having a gap size (the width of the gap between the wiring layers and the semiconductor device) in the range of about 10 to 200 μm is preferable, and in this case, in order to improve permeation of the sealing resin into the gap, it is preferable to use the inorganic filler having an average particle diameter of 0.1 to 5 μm, preferably 0.5 to 2 μm, and 0.1% by mass or less, in particular, 0 to 0.08% by mass of which has a particle diameter of ½ or more of the gap size of the flip chip type semiconductor device based on the amount of the whole inorganic filler. If the average particle size is 0.1 μm or more, there is no fear that the viscosity becomes too high, while if the average particle diameter is 5 μm or less, there is no fear that the inorganic filler will be caught in the gap and unfilled. In particular, it is preferable to use an inorganic filler having an average particle diameter of about 1/10 or less and a maximum particle diameter of ⅓ or less with respect to the gap size.

In the flip chip type semiconductor device with a narrow gap type having a gap size of 20 μm, for example, it is preferable to use an inorganic filler having a ratio of the particle size exceeding 10 μm of 0.1% by mass or less based on the whole inorganic filler. If the material having the particle size is 0.1% by mass or less, there is no fear that the inorganic filler is caught in the gap to cause filling failure and voids.

Here, as a method for measuring particles having a particle size of ½ or more of the gap size, for example, there may be employed a particle size inspection method in which an inorganic filler and pure water are mixed with a ratio of 1:9 (mass), aggregates are sufficiently collapsed by subjecting to ultrasonic treatment, the resulting material is sieved with a filter having openings of ½ of the gap size, and the remaining amount on the sieve is weighed.

### [Other Additives]

In the composition for forming the sealing resin layer may be blended, if necessary, other additives in addition to the components. Such additives may be mentioned, for example, an antimony compound such as antimony trioxide, a molybdenum compound such as zinc molybdate-carried talc and zinc molybdate-carried zinc oxide, a phosphazene compound, a hydroxide such as aluminum hydroxide and magnesium hydroxide, a flame retardant such as zinc borate and zinc stannate, a colorant such as carbon black, a halogen ion trapping agent such as hydrotalcite.

[Manufacturing Method of Sealing Material Attached with Base Material for Sealing Semiconductor]

The sealing material attached with a base material for sealing a semiconductor to be used in the present invention can be manufactured by forming a sealing resin layer onto one of the surfaces of the base material. The sealing resin layer can be formed by various methods such as a method in which a composition containing an uncured or semi-cured thermosetting resin (the composition for forming the sealing resin layer) is laminated onto one of the surfaces of the base material in a sheet state or a film state by using vacuum lamination, high temperature vacuum press or heating roll, a method in which a composition containing a thermosetting resin such as a liquid-state epoxy resin and silicone resin is coated by printing or dispense under reduced pressure or in vacuum and heating the material, and a method in which a composition containing an uncured or semi-cured thermosetting resin is subjected to press molding.

In the sealing process of the method for manufacturing a semiconductor apparatus of the present invention, the device-mounted surface of the semiconductor device-mounted substrate is collectively sealed by using the sealing material attached with a base material for sealing a semiconductor.

### <Substrate Removal Process>

In the method for manufacturing a semiconductor apparatus of the present invention, the substrate is then removed from the semiconductor device-mounted substrate in which the device-mounted surface is collectively sealed. As a method of removing the substrate, there may be mentioned a method of removing by grinding or etching. In the case where a temporary adhesive layer is formed between the substrate and the wiring layers in the preparation process, it is also possible to lower the adhesive force by UV or laser, and the material can be separated between the temporary adhesive layer and the wiring layers from each other.

### <Bump Forming Process>

In the method for manufacturing a semiconductor apparatus of the present invention, after removing the substrate, it is preferable to form electrodes such as bumps onto the surface (that is, the wiring layers) exposed by the removal of the substrate. According to this procedure, a semiconductor apparatus assembly (a semiconductor apparatus in which a plurality of semiconductor devices are collectively sealed) in which the substrate is removed and electrodes are formed can be manufactured.

The method of forming the bumps is not particularly limited, and it can be performed by a conventionally known method such as solder ball or solder plating.

### <Dicing Process>

In the method for manufacturing a semiconductor apparatus of the present invention, it is preferable to divide the assembly into pieces by dicing after forming the electrodes. According to this procedure, the semiconductor apparatus divided into pieces is manufactured. Further, printing with a laser mark may be carried out on diced and individualized pieces.

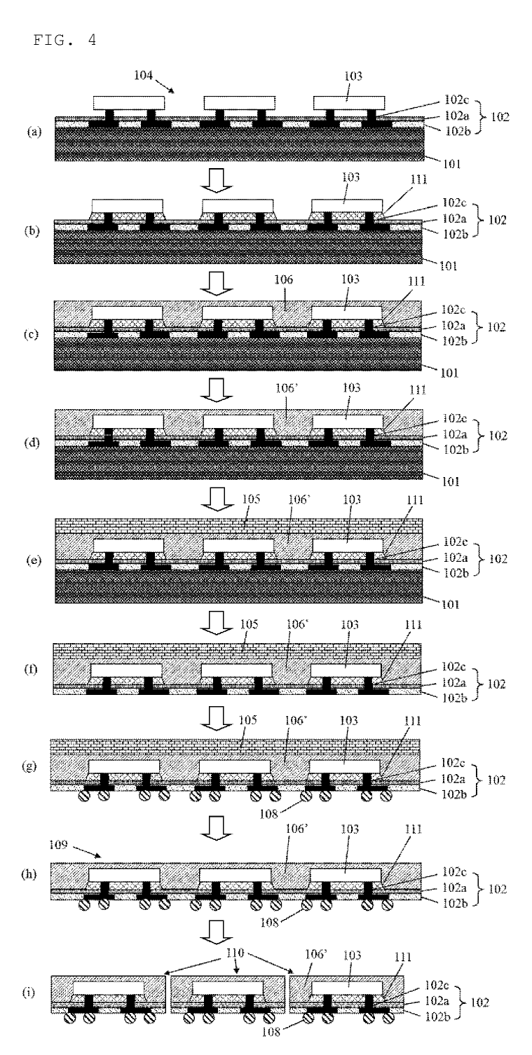

A schematic cross-sectional view of one example of a semiconductor device manufactured by such a manufacturing method of the present invention is shown in FIG. 3. The semiconductor apparatus 10 of FIG. 3 is a material in which the flip chip type semiconductor device 3 is sealed by the sealing resin layer 6′ after curing, and the base material 5 of the sealing material attached with a base material for sealing a semiconductor is provided on the surface side of the sealing resin layer 6′ after curing and the wiring layers 2 comprising the insulating layer 2a, the insulating layer 2b and plating pattern 2c, and further bumps 8 are provided on the opposite side (the side of the flip-chip type semiconductor device 3).

Here, the method for manufacturing a semiconductor apparatus of the present invention and a conventional method for manufacturing a semiconductor apparatus will be described in comparison.

FIG. 4 is a schematic cross-sectional view showing one example of a flow in the case of manufacturing a fan-out wafer level package by the conventional method for manufacturing a semiconductor apparatus using a general sealing resin. In the method for manufacturing a semiconductor apparatus of FIG. 4, a semiconductor device-mounted substrate 104 in which a plurality of flip chip type semiconductor devices 103 are mounted on a wiring layers 102 (an insulating layer 102a, an insulating layer 102b and a plating pattern 102c) formed on a substrate 101 is firstly prepared (FIG. 4(a): preparation process). Next, an underfill material 111 is allowed to enter into the space between the flip chip type semiconductor device 103 and the wiring layers 102 and cured (FIG. 4(b): underfilling process). Then, the device-mounted surface of the underfilled semiconductor device-mounted substrate 104 is cured and sealed by a sealing resin 106. According to this procedure, the sealing resin 106 becomes a sealing resin 106′ after curing (FIGS. 4(c) and (d): sealing process). Next, a support substrate 105 is bonded onto the sealing resin 106′ after curing (FIG. 4(e): support substrate bonding process). Then, the substrate 101 is removed by grinding or etching (FIG. 4(f): substrate removal process), and bumps 108 are formed onto the wiring layers 102 exposed by the removal of the substrate 101 (FIG. 4(g): bump forming process). Next, the support substrate 105 bonded in the support substrate bonding process is removed (FIG. 4(h): support substrate removal process). Then, the semiconductor apparatus assembly 109 thus obtained is divided into pieces by dicing to manufacture a semiconductor apparatus 110 (FIG. 4(i): dicing process).

When FIG. 1 and FIG. 4 are compared to each other, it can be understood that the method for manufacturing a semiconductor apparatus of the present invention of FIG. 1 has a smaller number of processes and the manufacturing process can be simplified. In the following, the process which can be omitted in the present invention will be described in more detail.

In the conventional method for manufacturing a semiconductor apparatus, the underfilling process and the sealing process are carried out in separate processes as shown in FIG. 4. In general, in the case where the underfilling and collective sealing of the device-mounted surface are carried out simultaneously, it is necessary to reduce the size (particle diameter) of the filler to be incorporated into the sealing resin. However, if the size of the filler is decreased, the specific surface area of the filler is increased and the melt viscosity of the sealing resin is increased, so that it is difficult to blend the filler at a high level. In addition, the expansion coefficient of the sealing resin becomes high so that warpage after sealing is a serious problem. Thus, it is difficult to achieve both of subjecting to the underfilling and collective sealing of the device-mounted surface simultaneously, and suppressing warpage by using a general sealing resin. To the contrary, in the method for manufacturing a semiconductor apparatus of the present invention as shown in FIG. 1, warpage can be suppressed by the base material by using the sealing material attached with a base material for sealing a semiconductor. Accordingly, the degree of freedom of physical properties of the sealing resin layer is increased, and the underfilling and collective sealing of the device-mounted surface can be carried out in the sealing process simultaneously. Thus, according to the present invention, it is possible to omit the underfilling process which is required to be separately carried out in the conventional method.

In addition, in the case of removing the substrate after sealing the device-mounted surface of the semiconductor device-mounted substrate by using a general sealing resin, cracks, chips and twisting occur during the removal process and after the removal process, so that it is usual to carry out the removal of the substrate after bonding the support substrate to the side of the sealing resin layer. Therefore, in the conventional method for manufacturing a semiconductor apparatus, the support substrate bonding process was carried out after the sealing process as shown in FIG. 4. To the contrary, in the method for manufacturing a semiconductor apparatus of the present invention as shown in FIG. 1, it is possible to obtain a molded product having extremely high strength due to the reinforcing effect of the base material can be obtained by using the sealing material attached with a base material for sealing a semiconductor. Accordingly, it is possible to remove the substrate without bonding the support substrate to the side of the sealing resin layer. Thus, according to the present invention, it is possible to omit the supporting substrate bonding process, which has been required to be separately carried out in the conventional method.

In addition, in the case of using the support substrate, it is necessary to remove the support substrate before dicing. The support substrate removing process is generally carried out by the method of grinding or etching similarly to the substrate removing process, or in the case where a temporary adhesive layer is formed between the support substrate and the sealing resin layer in the support substrate bonding process, it is carried out by the method in which an adhesive force is lowered by UV or laser, and the material is peeled off between the temporary adhesive layer and the wiring layers. To the contrary, in the method for manufacturing a semiconductor apparatus of the present invention as shown in FIG. 1, the support substrate is not required to be used so that the support substrate is not required to be removed as a matter of course. Thus, according to the present invention, it is also possible to omit the support substrate removing process, which has been required to be separately carried out in the conventional method.

According to the method for manufacturing a semiconductor apparatus of the present invention, it is possible to accomplish reduction in manufacturing cost and improvement in yield by omitting (shortening) and simplifying some processes which were necessary for manufacture of the semiconductor apparatus, in particular the fan-out wafer level package, without causing sealing defects such as voids and warpage.

### EXAMPLES

In the following, the present invention will be specifically explained by referring to Examples and Comparative examples, but the present invention is not limited by these.

### <Manufacture of Base Material>

300 parts by mass of toluene was added to 60 parts by mass of a cresol-novolac type epoxy resin (trade name: EPICLON-N695, available from DIC CORPORATION), 30 parts by mass of a phenol-novolac resin (trade name: TD2090, available from DIC CORPORATION), 3 parts by mass of carbon black (trade name: 3230B, available from Mitsubishi Chemical Corporation) as black pigment and 0.6 part by mass of a catalyst TPP (triphenylphosphine), and the mixture was mixed by stirring to prepare a toluene dispersion of an epoxy resin composition. An E glass cloth (available from Nitto Boseki Co., Ltd., a thickness: 150 μm) was dipped as a fiber base material in the toluene dispersion of the epoxy resin composition to impregnate the toluene dispersion of the epoxy resin composition into the E glass cloth. The glass cloth was allowed to stand at 120° C. for 15 minutes to volatilize the toluene. The glass cloth was molded by heating at 175° C. for 5 minutes to obtain a molded product, and the product was further heated at 180° C. for 4 hours (secondary curing) to cure the impregnated epoxy resin composition whereby an epoxy resin-impregnated fiber base material X1 having a size of 400 mm×500 mm and a thickness of 0.16 mm in which cured product layers of the epoxy resin composition have been formed onto the both surfaces of the fiber base material layer was obtained. The linear expansion coefficient of the epoxy resin-impregnated fiber base material X1 from 0° C. to 200° C. was 9 to 13 ppm/° C.

<Preparation of Resin Composition which Becomes Sealing Resin Layer>

60 parts by mass of a cresol-novolac type epoxy resin (trade name: EPICLON-N655, available from DIC CORPORATION), 30 parts by mass of a phenol-novolac resin (trade name: BRG555, available from Showa Highpolymer Co., Ltd.), 400 parts by mass of spherical silica having an average particle size of 1.2 μm (trade name: SO-32R, available from Admatechs), 0.2 part by mass of a catalyst TPP (triphenylphosphine), 0.5 part by mass of a silane coupling agent: 3-glycidoxypropyltrimethoxysilane (trade name: KBM403, available from Shin-Etsu Chemical Co., Ltd.), and 3 parts by mass of carbon black (trade name: 3230B, available from Mitsubishi Chemical Corporation) as a black pigment were sufficiently mixed by a high speed mixing device, heated and kneaded by a continuous kneading device, and then, extruded from a T-die to obtain a sheet state thermosetting resin composition Y1 having a size of 390 mm×490 mm and a thickness of 0.3 mm. The minimum melt viscosity of the thermosetting resin composition Y1 measured from 100° C. to 200° C. by a parallel plate type viscoelasticity measurement apparatus (device name: MR-300, manufactured by Rheology Co.) was 30 Pa·s.

<Manufacture of Sealing Material Attached with Base Material for Sealing Semiconductor>

The sheet state thermosetting resin composition Y1 was mounted onto the epoxy resin-impregnated fiber base material X1, and the materials were laminated under the conditions of a vacuum degree of 50 Pa, a temperature of 50° C. and a time of 60 seconds by using a vacuum laminator manufactured by Nikko Materials K.K. to prepare a sealing material Z1 attached with a base material for sealing a semiconductor.

### <Manufacture of Semiconductor Device-Mounted Substrate>

A copper film was formed on a silicon wafer having a diameter of 200 mm and a thickness of 725 μm by vapor deposition, and a thermosetting phenol-modified silicone resist composition was applied by spin coating and pre-baked under the conditions at 100° C. for 100 seconds to form a resist film having a thickness of 10 μm. Then, a mask for forming an objective pattern was placed over the resist film, and an energy beam with a wavelength of 320 nm was irradiated at an exposure amount of about 1 to 5,000 mJ/cm². Further, an objective pattern was formed on the substrate by developing with an aqueous alkaline solution of 2% by mass of tetramethylammonium hydroxide (TMAH) according to a puddle method for 3 minutes. By applying asking by oxygen plasma to the substrate on which the pattern is formed, minute resist residues on the pattern are removed and the resist surface is subjected to hydrophilization treatment, subsequently copper plating is carried out by electroless method to form a metal pattern on the substrate. A commercially available adhesive was applied to the four corners of a 10 mm square and 200 μm thick chip on which dummy bumps have been formed and bonded onto the substrate on which the metal pattern has been formed. The dummy bump diameter is 30 μm, the bump pitch is 60 μm, and a gap of 30 μm is formed between the chip and the resist film.

### <Manufacture of Support Substrate>

A borosilicate glass plate (trade name: TEMPAX Float, manufactured by SCHOTTJENAer GLAS Co.) having a thickness of 1 mm was cut into a size of 8 inches (200 mm) in diameter to prepare a support substrate. The support substrate and the sealing resin layer were bonded by using an adhesive (trade name: SFX-513S, available from Shin-Etsu Chemical Co., Ltd.).

Semiconductor apparatuses were manufactured by using the materials thus prepared and manufactured.

### Example 1

The sealing material attached with a base material for sealing a semiconductor Z1 and the semiconductor device-mounted substrate were compressed and molded under conditions of a degree of vacuum of 2,000 Pa, a pressure of 1.0 MPa at 150° C. for 300 seconds by using a vacuum press manufactured by Nikko Materials Co., to carry out curing and sealing. After curing and sealing, when it was post-cured at 150° C. for 4 hours and the substrate was removed by using a grinder (device name: DAG810, manufactured by Disco Corporation) to expose the wiring layers. Solder paste was printed at a predetermined position on the exposed wiring layers by using a printing machine (device name: DEK HORIZON APi, manufactured by DEK), and reflow was carried out by using a reflow apparatus (device name: TNP40, manufactured by Tamura Corporation) with the highest reachable temperature of 265° C. Further, the product was divided into pieces by using a Dicer (device name: DAD323, manufactured by Disco Corporation). Workability was good through a series of processes from compression molding to dividing into pieces.

### Example 2

The sealing material attached with a base material for sealing a semiconductor Z1 and the semiconductor device-mounted substrate were compressed and molded under conditions of a degree of vacuum of 100 Pa, a pressure of 5.0 MPa at 175° C. for 180 seconds by using a vacuum press manufactured by Nikko Materials Co., to carry out curing and sealing. After post-curing after curing and sealing, the same operation as in Example 1 was carried out and dividing into pieces were carried out. Workability was good through a series of processes from compression molding to dividing into pieces.

### Comparative Example 1

The thermosetting resin composition Y1 and the semiconductor device-mounted substrate were compressed and molded under conditions of a degree of vacuum of 100 Pa, a pressure of 5.0 MPa at 175° C. for 180 seconds by using a vacuum press manufactured by Nikko Materials Co., to carry out curing and sealing. After curing and sealing, when it was post-cured at 150° C. for 4 hours and the substrate was removed by using a grinder (device name: DAG810, manufactured by Disco Corporation) to expose the wiring layers, then warpage becomes extremely large so that formation of the electrodes of the next process could not be carried out.

### Comparative Example 2

The thermosetting resin composition Y1 and the semiconductor device-mounted substrate were compressed and molded under conditions of a degree of vacuum of 100 Pa, a pressure of 5.0 MPa, at 175° C. for 180 seconds by using a vacuum press manufactured by Nikko Materials Co., to carry out curing and sealing. After curing and sealing, it was post-cured at 150° C. for 4 hours, and then, the support substrate was bonded to the side of the sealing resin layer. Thereafter, the substrate was removed by grinding using a grinder (device name: DAG810, manufactured by Disco Corporation) to expose the wiring layers. Solder paste was printed at a predetermined position on the exposed wiring layers by using a printing machine (device name: DEK HORIZON APi, manufactured by DEK), and reflow was carried out by using a reflow apparatus (device name: TNP40, manufactured by Tamura Corporation) with the highest reachable temperature of 265° C. Further, the support substrate was removed by grinding by using a grinder (device name: DAG 810, manufactured by Disco Corporation). The molded product after removal of the support substrate was very brittle and cracks were entered before dividing into pieces by dicing. In addition, processes were many and complicated.

In Examples 1 and 2 in which the semiconductor apparatus was manufactured by the manufacturing process of the present invention, the workability was good through a series of processes from compression molding to dividing into pieces, and the manufacturing process of the semiconductor apparatus could be shortened without causing coating failure such as voids, and warpage. On the other hand, in Comparative example 1 in which it was sealed by the thermosetting resin composition without using the sealing material attached with a base material for sealing a semiconductor and the support substrate, and in Comparative example 2 in which it was sealed by the thermosetting resin composition without using the sealing material attached with a base material for sealing a semiconductor, thereafter, the support substrate was bonded, the semiconductor apparatus could not be manufactured since warpage occurred or cracks were generated in the molded product. From this fact, according to the method for manufacturing a semiconductor apparatus of the present invention, it could be clarified that the manufacturing process of a semiconductor device, in particular, a fan-out package could be shortened without causing sealing failure such as voids, and warpage.

It is to be noted that the present invention is not restricted to the embodiments shown by Examples. The embodiments shown by Examples are merely examples so that any embodiments composed of substantially the same technical concept as disclosed in the claims of the present invention and expressing a similar effect are included in the technical scope of the present invention.

### EXPLANATION OF THE REFERENCE NUMERALS

1 . . . Substrate,
2 . . . Wiring layer,
2a, 2b . . . Insulation layer,
2c . . . Plated pattern,
3 . . . Flip chip type semiconductor device,
4 . . . Semiconductor device-mounted substrate,
5 . . . Base material,
6 . . . Sealing resin layer,
6′ . . . Sealing resin layer after curing,
7 . . . Sealing material attached with base material for sealing semiconductor,
8 . . . Bumps,
9 . . . Semiconductor apparatus assembly,
10 . . . Semiconductor apparatus.

1. A method for manufacturing a semiconductor apparatus which comprises
preparing a semiconductor device-mounted substrate onto which a plurality of flip chip type semiconductor devices have been mounted onto a wiring layer formed on the substrate,
collectively sealing a device-mounted surface of the semiconductor device-mounted substrate with a sealing material attached with a base material for sealing a semiconductor having a base material and a sealing resin layer containing an uncured or semi-cured thermosetting resin component formed on one surface of the base material, and
removing the substrate from the collectively sealed semiconductor device-mounted substrate.

2. The method for manufacturing a semiconductor apparatus according to claim 1, wherein
collective sealing with the sealing material attached with a base material for sealing a semiconductor is carried out at a molding temperature of 80° C. to 200° C., and a molding pressure of 0.2 to 30 MPa under reduced pressure of a vacuum pressure of 10,000 Pa or lower.

3. The method for manufacturing a semiconductor apparatus according to claim 1, wherein
electrodes are formed on a surface exposed by removal of the substrate after removing the substrate.

4. The method for manufacturing a semiconductor apparatus according to claim 2, wherein
electrodes are formed on a surface exposed by removal of the substrate after removing the substrate.

5. The method for manufacturing a semiconductor apparatus according to claim 3, wherein
the semiconductor apparatus is divided into individual pieces by dicing after forming the electrodes.

6. The method for manufacturing a semiconductor apparatus according to claim 4, wherein
the semiconductor apparatus is divided into individual pieces by dicing after forming the electrodes.

7. The method for manufacturing a semiconductor apparatus according to claim 1, wherein
the base material is a fiber-containing resin base material in which a thermosetting resin composition is impregnated into a fiber base material and cured, and having a linear expansion coefficient of 3 to 20 ppm/° C. in the range of 0° C. to 200° C.

8. The method for manufacturing a semiconductor apparatus according to claim 2, wherein
the base material is a fiber-containing resin base material in which a thermosetting resin composition is impregnated into a fiber base material and cured, and having a linear expansion coefficient of 3 to 20 ppm/° C. in the range of 0° C. to 200° C.

9. The method for manufacturing a semiconductor apparatus according to claim 3, wherein
the base material is a fiber-containing resin base material in which a thermosetting resin composition is impregnated into a fiber base material and cured, and having a linear expansion coefficient of 3 to 20 ppm/° C. in the range of 0° C. to 200° C.

10. The method for manufacturing a semiconductor apparatus according to claim 4, wherein
the base material is a fiber-containing resin base material in which a thermosetting resin composition is impregnated into a fiber base material and cured, and having a linear expansion coefficient of 3 to 20 ppm/° C. in the range of 0° C. to 200° C.

11. The method for manufacturing a semiconductor apparatus according to claim 5, wherein
the base material is a fiber-containing resin base material in which a thermosetting resin composition is impregnated into a fiber base material and cured, and having a linear expansion coefficient of 3 to 20 ppm/° C. in the range of 0° C. to 200° C.

12. The method for manufacturing a semiconductor apparatus according to claim 6, wherein
the base material is a fiber-containing resin base material in which a thermosetting resin composition is impregnated into a fiber base material and cured, and having a linear expansion coefficient of 3 to 20 ppm/° C. in the range of 0° C. to 200° C.

13. The method for manufacturing a semiconductor apparatus according to claim 1, wherein
the sealing resin layer is a material which contains an inorganic filler, an amount of the inorganic filler is 80 to 95% by mass based on a whole composition for forming the sealing resin layer, and a minimum melt viscosity is 0.1 to 300 Pa·s at 100° C. to 200° C. in a state before curing the sealing resin layer.

14. The method for manufacturing a semiconductor apparatus according to claim 2, wherein
the sealing resin layer is a material which contains an inorganic filler, an amount of the inorganic filler is 80 to 95% by mass based on a whole composition for forming the sealing resin layer, and a minimum melt viscosity is 0.1 to 300 Pa·s at 100° C. to 200° C. in a state before curing the sealing resin layer.

15. The method for manufacturing a semiconductor apparatus according to claim 3, wherein
the sealing resin layer is a material which contains an inorganic filler, an amount of the inorganic filler is 80 to 95% by mass based on a whole composition for forming the sealing resin layer, and a minimum melt viscosity is 0.1 to 300 Pa·s at 100° C. to 200° C. in a state before curing the sealing resin layer.

16. The method for manufacturing a semiconductor apparatus according to claim 5, wherein
the sealing resin layer is a material which contains an inorganic filler, an amount of the inorganic filler is 80 to 95% by mass based on a whole composition for forming the sealing resin layer, and a minimum melt viscosity is 0.1 to 300 Pa·s at 100° C. to 200° C. in a state before curing the sealing resin layer.

17. The method for manufacturing a semiconductor apparatus according to claim 7, wherein
the sealing resin layer is a material which contains an inorganic filler, an amount of the inorganic filler is 80 to 95% by mass based on a whole composition for forming the sealing resin layer, and a minimum melt viscosity is 0.1 to 300 Pa·s at 100° C. to 200° C. in a state before curing the sealing resin layer.

18. The method for manufacturing a semiconductor apparatus according to claim 1, wherein
underfill between the flip chip type semiconductor device and the wiring layer is not carried out in advance, but carried out the underfill simultaneously with the collectively sealing a sealing material attached with a base material for sealing a semiconductor.

19. The method for manufacturing a semiconductor apparatus according to claim 1, wherein
a fan-out wafer level package is manufactured as the semiconductor apparatus.
